(19) United States
(12) Patent Application Publication
(10) Pub. No.: US 2006/0057746 A1
(43) Pub. Date: Mar. 16, 2006

(54) Semiconductor device fabrication method and apparatus

(76) Inventors: Seiji Inumiya, Kanagawa (JP); Motoyuki Sato, Kanagawa (JP); Akio Kaneko, Kanagawa (JP); Katsuyuki Sekine, Kanagawa (JP); Kazuhiro Eguchi, Kanagawa (JP)

Correspondence Address: Finnegan, Henderson, Farabow,;Garrett & Dunner, L.L.P., 1300 I Street, N.W., Washington, DC, 20005-3315, US

(21) Appl. No.: 10/986,408

(22) Filed: Nov. 12, 2004

(30) Foreign Application Priority Data
Sep. 10, 2004 (JP) 2004-264149

(51) Int. Cl. H01L 21/66

(52) U.S. Cl. 438/14

(57) ABSTRACT

According to the present invention, there is provided a semiconductor device fabrication method, comprising: depositing a film made of an insulating material on a surface of a semiconductor substrate; measuring a film thickness and/or composition of the film; setting nitriding conditions or oxidation conditions on the basis of the measurement result; and nitriding or oxidizing the film on the basis of the set nitriding conditions or oxidation conditions.

### CROSS REFERENCE TO RELATED APPLICATION

This application is based upon and claims benefit of priority under 35 USC §119 from the Japanese Patent Application No. 2004-264149, filed on Sep. 10, 2004, the entire contents of which are incorporated herein by reference.

### BACKGROUND OF THE INVENTION

The present invention relates to a semiconductor device fabrication method and apparatus.

A silicon oxynitride (SiON) film is used as the material of a gate insulating film in a MOS transistor. As a method of forming this film, a method by which nitrogen is doped by exposing a silicon oxide (SiO₂) film to a nitrogen plasma is used.

In this method, if nitridation is performed under the same conditions although the film thickness of the silicon oxide film as a base has variations, the final equivalent oxide thickness varies. This varies the characteristics of the MOS transistor.

A method of oxidizing a silicon nitride (Si₃N₄) film is also proposed as a method of forming a silicon oxynitride film having a high nitrogen concentration. In this method, as in the above method, if oxidation is performed under the same conditions although the film thickness of the silicon nitride film as a base has variations, the final film equivalent oxide thickness varies, and the characteristics of the MOS transistor also vary.

Furthermore, thinning of the silicon oxide film or silicon nitride film used as the material of a gate insulating film in a MOS transistor faces its physical limits.

Accordingly, nitrided silicate such as hafnium silicon oxynitride (HfSiON) are attracting attention as a substitute material having a dielectric constant higher than those of the silicon oxide film and silicon nitride film, and a resistance to high-temperature process in the semiconductor fabrication process.

Unfortunately, a nitrided silicate is a film deposited by CVD or the like, unlike the silicon oxide film formed by oxidizing a semiconductor substrate. Since the deposited film has large variations in film thickness, the final equivalent oxide thickness varies, and this varies the characteristics of the MOS transistor.

References disclosing the conventional gate insulating film fabrication methods are as follows.

1: Japanese Patent Laid-Open No. 2004-31760

2: Japanese Patent Laid-Open No. 2002-33320

3: Japanese Patent Laid-Open No. 2000-124154

4: Japanese Patent Laid-Open No. 2003-142482

5: U.S. Pat. No. 6,444,036

### SUMMARY OF THE INVENTION

According to one aspect of the invention, there is provided a semiconductor device fabrication method, comprising:

depositing a film made of an insulating material on a surface of a semiconductor substrate;

measuring a film thickness and/or composition of the film;

setting nitriding conditions or oxidation conditions on the basis of the measurement result; and

nitriding or oxidizing the film on the basis of the set nitriding conditions or oxidation conditions.

According to one aspect of the invention, there is provided a semiconductor device fabrication method, comprising:

depositing an oxide film containing a metal element on a surface of a semiconductor substrate;

measuring a film thickness and/or composition of the oxide film;

setting nitriding conditions on the basis of the measurement result; and

nitriding the oxide film on the basis of the set nitriding conditions.

According to one aspect of the invention, there is provided a semiconductor device fabrication method, comprising:

depositing an oxide film or nitride film on a surface of a semiconductor substrate;

measuring a film thickness of the oxide film or nitride film;

setting nitriding conditions or oxidation conditions on the basis of the measurement result; and

nitriding the oxide film on the basis of the set nitriding conditions, or oxidizing the nitride film on the basis of the set oxidation conditions.

According to one aspect of the invention, there is provided a semiconductor device fabrication apparatus comprising:

a depositing apparatus which deposits a film made of an insulating material on a surface of a semiconductor substrate;

a film thickness measurement apparatus which measures a film thickness of the film and/or a composition measurement apparatus which measures a composition of the film;

a process controller which sets nitriding conditions or oxidation conditions on the basis of the measurement results obtained by said film thickness measurement apparatus and/or composition measurement apparatus; and

a nitriding apparatus which nitrides the film or an oxidizing apparatus which oxidizes the film on the basis of the nitriding conditions or oxidation conditions set by said process controller.

### BRIEF DESCRIPTION OF THE DRAWINGS

FIG. 1 is a flowchart showing the procedure of a semiconductor device fabrication method according to the first embodiment of the present invention;

FIG. 2 is a longitudinal sectional view of a certain process of the semiconductor device fabrication method according to the first embodiment of the present invention;

FIG. 3 is a graph which is referred to in the semiconductor device fabrication method according to the first embodiment, and which shows the relationship between the film thickness, the plasma nitriding time, and the equivalent oxide thickness;

FIG. 4 is a longitudinal sectional view of a certain process of the semiconductor device fabrication method according to the first embodiment of the present invention;

FIG. 5 is a longitudinal sectional view of a certain process of the semiconductor device fabrication method according to the first embodiment of the present invention;

FIG. 6 is a graph which is referred to in the semiconductor device fabrication method according to the first embodiment, and which shows the relationship between the film composition, the plasma nitriding time, and the equivalent oxide thickness; and

FIG. 7 is a schematic view showing the arrangement of a semiconductor device fabrication apparatus according to the second embodiment.

### DETAILED DESCRIPTION OF THE INVENTION

Embodiments of the present invention will be described below with reference to the accompanying drawings.

### (1) First Embodiment

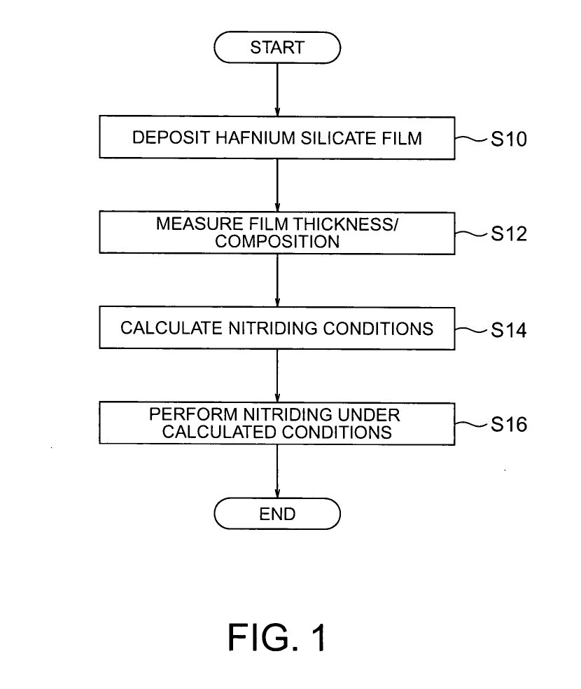

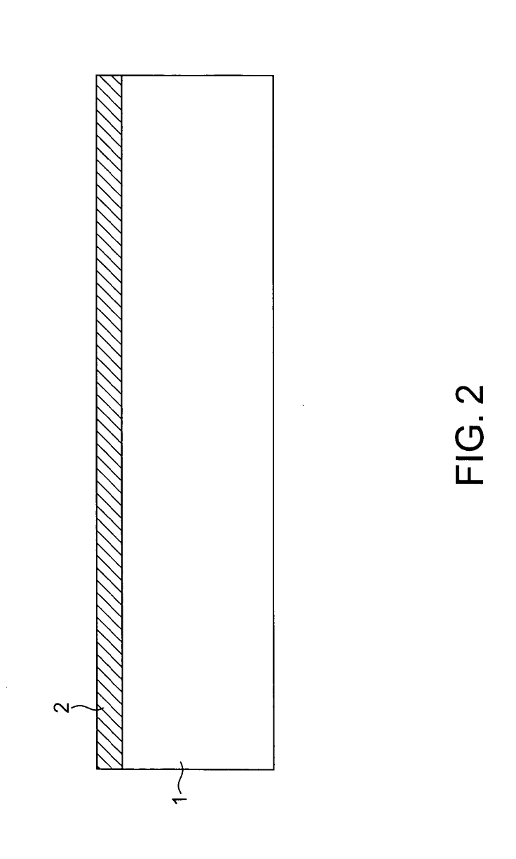

FIG. 1 is a flowchart showing the procedure of a semiconductor device fabrication method according to the first embodiment of the present invention. FIGS. 2, 4, and 5 illustrate the longitudinal sections of elements in different processes. In the first embodiment, a hafnium silicon oxynitride film is used as a gate insulating film.

Referring to FIG. 2, a device isolation film (not shown) is formed in a surface portion of a semiconductor substrate 1 by using the conventional STI (Shallow Trench Isolation) method.

In step S10 of FIG. 1, MOCVD (Metal Organic Chemical Vapor Deposition) is used to deposit a 2-nm thick hafnium silicate film 2 in an active area, the surface of which is exposed, of the semiconductor substrate 1. Subsequently, annealing is performed for 60 sec in a 0.1 mTorr oxygen ambient at 800° C.

In step S12, ellipsometry, an X-ray fluorescence method, or the like is used to measure the film thickness of the hafnium silicate film 2.

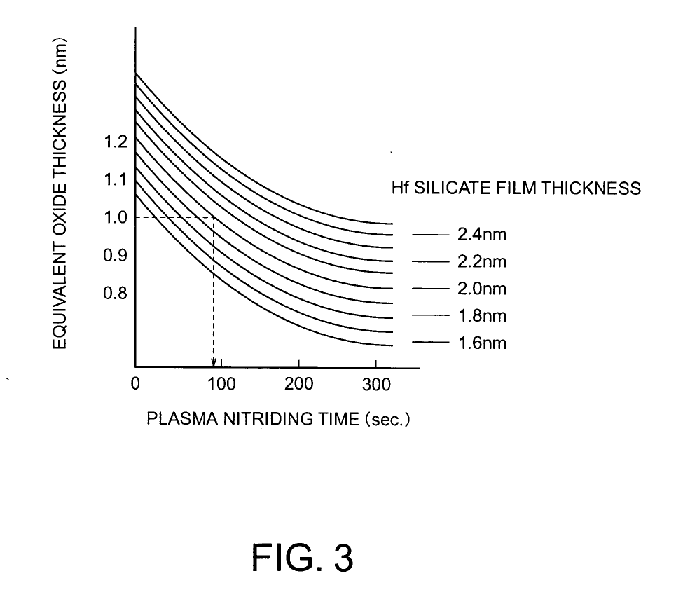

In step S14, the nitriding conditions are calculated. In this step, data shown in FIG. 3 is used. FIG. 3 shows the relationship between the plasma nitriding time and the equivalent oxide thickness. The equivalent oxide thickness is a film thickness calculated by taking account of the difference between the dielectric constants of materials, in this case the difference between the dielectric constants of hafnium silicon oxynitride and silicon oxide. From the film thickness (in this embodiment, 2 nm) of the hafnium silicate film 2 measured in step S12, a design value of the equivalent oxide thickness is 1.0 nm, so the nitriding time is determined to 90 sec. The nitriding conditions of the nitrogen plasma ambient are 900 W and 20 mTorr.

In step S16, nitrogen is doped into the hafnium silicate film 2 by exposing it to the nitrogen plasma ambient under the determined nitriding conditions, i.e., 900 W and 20 mTorr, for 90 sec.

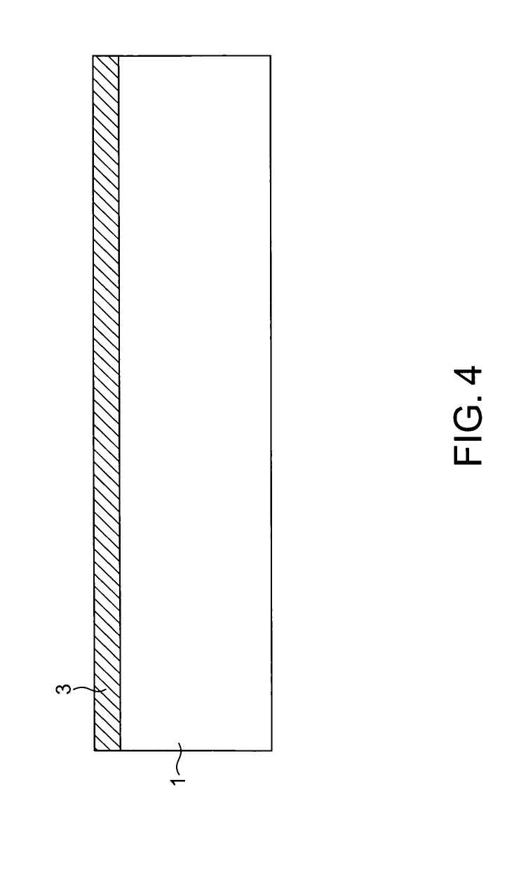

Immediately after that, annealing is performed in a 5 mTorr nitrogen ambient at 1,000° C. for 10 sec. As a consequence, a hafnium silicon oxynitride film 3 shown in FIG. 4 is formed.

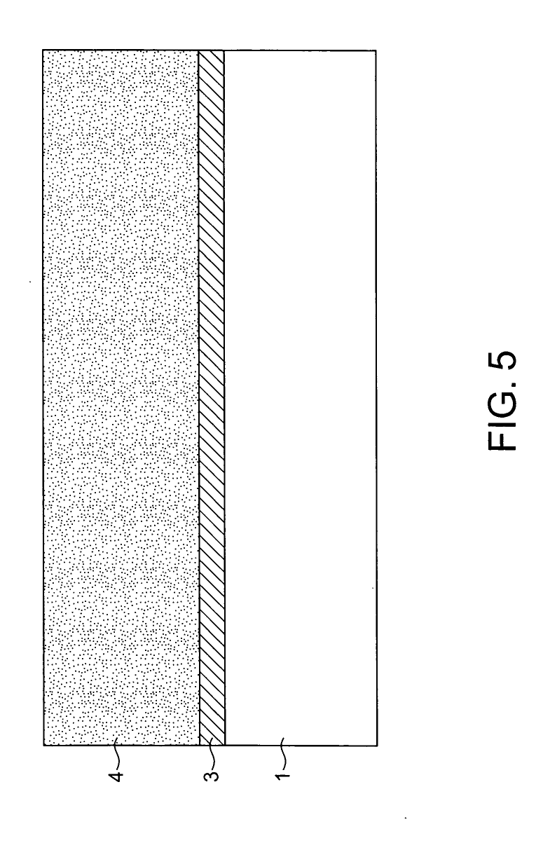

After that, as shown in FIG. 5, a 150-nm thick poly-crystalline silicon film 4 as a gate electrode material is deposited on the hafnium silicon oxynitride film 3 by using LPCVD.

After that, a MOSFET is completed by performing, e.g., gate electrode patterning, gate sidewall formation, source/drain region formation, silicide formation, and a wiring step as the conventional MOSFET formation processes.

The MOSFET thus obtained has undergone the nitriding process for the nitriding time which matches the measurement value of the film thickness of the hafnium silicate film 2. Therefore, this MOSFET has a gate insulating film made of a hafnium silicon oxynitride film 3 having an equivalent oxide thickness which matches the design value. 0.3 V, for example, is obtained as a threshold voltage matching the design value.

Even if the thickness of the hafnium silicate film 2 varies, therefore, a threshold voltage matching the design value can be obtained by adjusting the nitriding time in accordance with the film thickness.

In this embodiment, the thickness of the deposited hafnium silicate film 2 is measured in step S12, and the nitriding time is determined on the basis of this film thickness in step S14.

It is, however, also possible to measure the composition (Hf/(Hf+Si)) of the hafnium silicate film 2 by using X-ray fluorescence method or the like in step S12, instead of the film thickness measurement described above, and determine the nitriding time on the basis of the film thickness and composition in step S14.

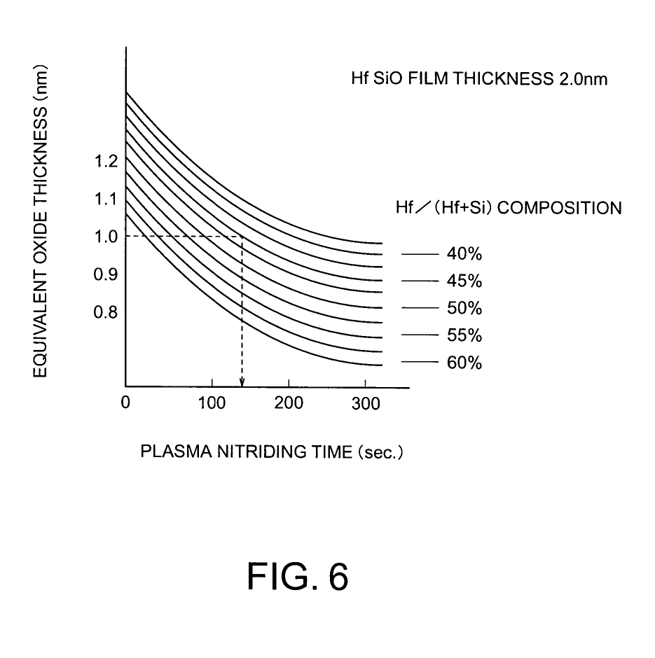

As shown in FIG. 6, for example, if the film thickness of the hafnium silicate film 2 is 2 nm and the composition (Hf/Hf+Si))=50% is the central value, a desired equivalent oxide thickness of 1.0 nm is obtained by performing nitriding for 90 sec as explained with reference to FIG. 5.

If the composition is 45%, however, it is necessary to perform nitriding for 140 sec as shown in FIG. 6 in order to obtain a desired equivalent oxide thickness of 1.0 nm.

As described above, the equivalent oxide thickness converted into the thickness of a silicon oxide film can also be obtained by adjusting the nitriding time by measuring the composition, instead of the film thickness. This makes it possible to form a MOS transistor having small variations.

Alternatively, the composition can be measured in addition to the film thickness. In this case, the equivalent oxide thickness can be calculated at higher accuracy.

In the first embodiment as described above, a desired equivalent oxide thickness can be obtained by changing the nitriding time in accordance with the film thickness or the film thickness and composition measured for each individual semiconductor device. Therefore, a semiconductor device having small variations in transistor threshold value can be obtained by using this film as a gate insulating film.

### (2) Second Embodiment

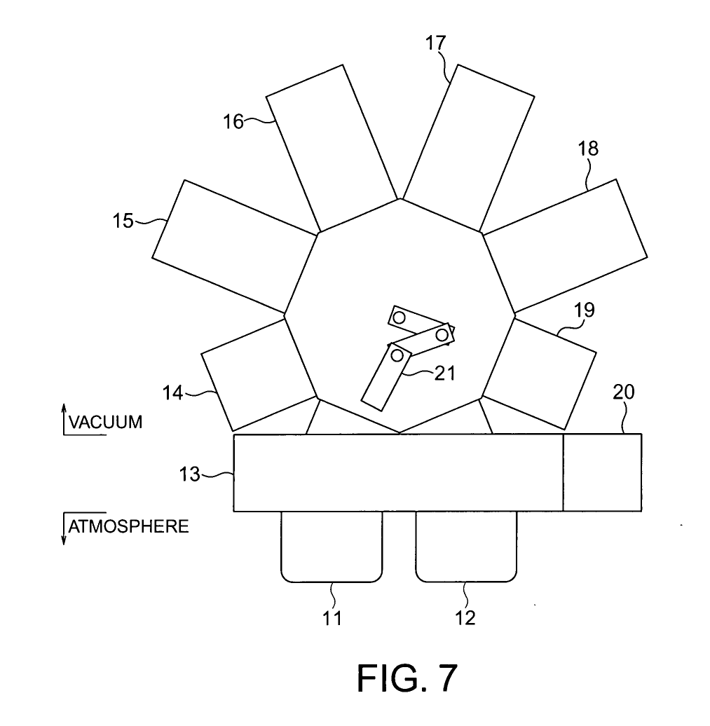

A semiconductor device fabrication apparatus according to the second embodiment of the present invention will be described below with reference to FIG. 7 showing the arrangement of the apparatus.

A semiconductor wafer accommodation chamber 11 or 12 accommodates a semiconductor wafer (not shown).

The semiconductor wafer accommodation chambers 11 and 12 are connected to a platform 13 which is connected to a film thickness measurement apparatus 14, MOCVD chamber 15, annealing chamber 16, plasma nitriding chamber 17, LPCVD (Low Pressure Chemical Vapor Deposition) chamber 18, and composition measurement apparatus 19.

The semiconductor wafer accommodation chambers 11 and 12 are in an atmospheric state, and the film thickness measurement apparatus 14, MOCVD chamber 15, annealing chamber 16, plasma nitriding chamber 17, LPCVD chamber 18, and composition measurement apparatus 19 are in a vacuum state. Accordingly, the platform 13 is equivalent to a space for changing air.

A semiconductor wafer accommodated in the semiconductor wafer accommodation chamber 11 or 12 is passed through the platform 13 and transferred to the film thickness measurement apparatus 14, MOCVD chamber 15, annealing chamber 16, plasma nitriding chamber 17, LPCVD chamber 18, and composition measurement apparatus 19 by an arm 21. The operation of each unit is controlled by a process controller 20.

The film thickness measurement apparatus 14 is used to measure the film thickness of, e.g., a hafnium silicate film, silicon oxide film, or silicon nitride film deposited or formed on the semiconductor wafer.

The MOCVD chamber 15 is used to deposit a desired film such as a hafnium silicate film on the semiconductor wafer by MOCVD.

The annealing chamber 16 is used to form a silicon oxide or silicon nitride films by oxidizing or nitriding the surface of the semiconductor wafer respectively, or perform necessary annealing in an oxygen ambient after the film is deposited.

The plasma nitriding chamber 17 is used to perform plasma nitriding after the film is deposited or formed.

The LPCVD chamber 18 is used to, e.g., deposit a gate insulating film such as a silicon oxide film or silicon nitride film, or deposit a poly-crystalline silicon film after the gate insulating film is formed.

The composition measurement apparatus 19 is used to measure the composition of a hafnium silicate film or the like, and can be, e.g., a X-ray fluorescence apparatus.

The process controller 20 controls the operation of each unit described above. In addition, the process controller 20 calculates nitriding or oxidation condition on the basis of the film thickness measured by the film thickness measurement apparatus 14 or the composition measured by the composition measurement apparatus 19, and controls necessary operations of nitriding or oxidation performed in the annealing chamber 16 or plasma nitriding chamber 17.

In addition to the above arrangement, it is also possible to use a film thickness measurement apparatus capable of measuring the film thickness of a fine region, and calculate an appropriate oxidation time or nitriding time from the film thickness measured by this apparatus.

The fabrication method of the first embodiment can be easily performed by using the fabrication apparatus of the second embodiment having the above arrangement.

In the second embodiment, the film thickness or composition of the deposited film is measured by the film thickness measurement apparatus 14 or composition measurement apparatus 19 included in the fabrication apparatus, and the process controller 20 in the same system determines appropriate nitriding or oxidation conditions on the basis of the measurement result, thereby performing the process. This eliminates external factors which cause measurement errors, and improves the accuracy when the optimal nitriding or oxidation conditions are calculated.

As described above, the semiconductor device fabrication method and apparatus according to the first and second embodiments described above can form a gate insulating film having small variations in equivalent oxide thickness, and can fabricate a semiconductor device including a MOS transistor having small variations in characteristics.

Each embodiment described above is an example, and does not limit the present invention. For example, although the formation of a hafnium silicon oxynitride film is described in the first embodiment, the present invention is also applicable to the formation of a high-dielectric oxynitride film containing another metal element such as Zr. Also, the present invention is similarly applicable to, e.g., nitriding after a silicon oxide film is formed, or oxidation after a silicon nitride film is formed.

That is, it is possible to measure the film thickness after a silicon oxide film is formed, and, on the basis of the measurement result, determine nitriding conditions including the nitriding time so that a desired equivalent oxide thickness is obtained. Likewise, it is possible to measure the film thickness after a silicon nitride film is formed, and, on the basis of the measurement result, determine oxidation conditions including the oxidation time so that a desired equivalent oxide thickness is obtained. In this manner, a desired equivalent thickness is obtained regardless of variations in film thickness of the formed silicon oxide film or silicon nitride film. When the obtained silicon oxynitride film is used as a gate insulating film, a threshold voltage matching a design value can be obtained. Note that when a metal element and silicon are contained as in a hafnium silicate film, the composition can be measured by measuring the composition ratio of the metal element and silicon as needed.

Similarly, although the fabrication apparatus of the second embodiment is explained as an apparatus for forming a hafnium silicon oxynitride film, the present invention is also applicable to nitriding or oxidation of another insulating film, e.g., nitriding of a silicon oxide film or oxidation of a silicon nitride film.

1. A semiconductor device fabrication method, comprising:
forming a film made of an insulating material on a surface of a semiconductor substrate;
measuring a film thickness and/or composition of the film;
setting nitriding conditions or oxidation conditions on the basis of the measurement result; and
nitriding or oxidizing the film on the basis of the set nitriding conditions or oxidation conditions.

2. A method according to claim 1, wherein the film thickness of the film is measured using ellipsometry or a X-ray fluorescence method.

3. A method according to claim 1, wherein when the nitriding conditions are set, a nitriding time is set by using data indicating a relationship between an equivalent oxide thickness and a plasma nitriding time.

4. A method according to claim 1, wherein the composition of the film is measured using a X-ray fluorescence method.

5. A method according to claim 1, wherein the film is a hafnium silicate film, and the hafnium silicate film is nitrided.

6. A method according to claim 1, wherein the film is a silicon nitride film, and the silicon nitride film is oxidized.

7. A method according to claim 1, wherein the film is a silicon oxide film, and the silicon oxide film is nitrided.

8. A semiconductor device fabrication method, comprising:
depositing an oxide film containing a metal element on a surface of a semiconductor substrate;
measuring a film thickness and/or composition of the oxide film;
setting nitriding conditions on the basis of the measurement result; and
nitriding the oxide film on the basis of the set nitriding conditions.

9. A method according to claim 8, wherein the film thickness of the film is measured using ellipsometry or a X-ray fluorescence method.

10. A method according to claim 9, wherein when the nitriding conditions are set, a nitriding time is set by using data indicating a relationship between an equivalent oxide thickness and a plasma nitriding time.

11. A method according to claim 8, wherein when the nitriding conditions are set, a nitriding time is set by using data indicating a relationship between an equivalent oxide thickness and a plasma nitriding time.

12. A method according to claim 8, wherein the composition of the film is measured using a X-ray fluorescence method.

13. A method according to claim 8, wherein the film is a hafnium silicate film, and the hafnium silicate film is nitrided.

14. A semiconductor device fabrication method, comprising:
depositing an oxide film or nitride film on a surface of a semiconductor substrate;
measuring a film thickness of the oxide film or nitride film;
setting nitriding conditions or oxidation conditions on the basis of the measurement result; and
nitriding the oxide film on the basis of the set nitriding conditions, or oxidizing the nitride film on the basis of the set oxidation conditions.

15. A method according to claim 14, wherein the film thickness of the film is measured using ellipsometry or a X-ray fluorescence method.

16. A method according to claim 15, wherein when the nitriding conditions are set, a nitriding time is set by using data indicating a relationship between an equivalent oxide thickness and a plasma nitriding time.

17. A method according to claim 14, wherein when the nitriding conditions are set, a nitriding time is set by using data indicating a relationship between an equivalent oxide thickness and a plasma nitriding time.

18. A method according to claim 14, wherein the film is a silicon nitride film, and the silicon nitride film is oxidized.

19. A method according to claim 14, wherein the film is a silicon oxide film, and the silicon oxide film is nitrided.

20. A semiconductor device fabrication apparatus comprising:
a forming apparatus which deposits a film made of an insulating material on a surface of a semiconductor substrate;
a film thickness measurement apparatus which measures a film thickness of the film and/or a composition measurement apparatus which measures a composition of the film;
a process controller which sets nitriding conditions or oxidation conditions on the basis of the measurement results obtained by said film thickness measurement apparatus and/or composition measurement apparatus; and
a nitriding apparatus which nitrides the film or an oxidizing apparatus which oxidizes the film on the basis of the nitriding conditions or oxidation conditions set by said process controller.
